(19) United States
(12) Patent Application Publication
(10) Pub. No.: US 2012/0293971 A1
(43) Pub. Date: Nov. 22, 2012

(54) ELECTRONIC DEVICE

(75) Inventor: Yu-Jen Tsai, Hsinchu (TW)

(73) Assignee: GEMTEK TECHNOLOGY CO., LTD., Hsinchu (TW)

(21) Appl. No.: 13/180,552

(22) Filed: Jul. 12, 2011

(30) Foreign Application Priority Data
May 20, 2011 (TW) 100117800

(51) Int. Cl. H05K 5/02

(52) U.S. Cl. 361/752

(57) ABSTRACT

An electronic device including a circuit board, a frame, at least one shielding cover, a shielding case and a plurality of electronic components is provided. The frame is disposed on the circuit board for forming a plurality of first containing spaces on the circuit board. The shielding cover is disposed on the frame and covers at least a part of the first containing spaces. The shielding cover comprises a plurality of folded portions. The folded portions are disposed in a part of the first containing spaces for dividing the first containing spaces into a plurality of second containing spaces. The shielding case is disposed on the circuit board and covers the shielding cover and the frame. The electronic components are disposed on the circuit board and located in at least one of the first containing spaces and the second containing spaces.

### CROSS-REFERENCE TO RELATED APPLICATION

This application claims the priority benefit of Taiwan application serial no. 100117800, filed May 20, 2011. The entirety of the above-mentioned patent application is hereby incorporated by reference herein and made a part of this specification.

### BACKGROUND OF THE INVENTION

1. Field of the Invention

The invention relates to an electronic device. Particularly, the invention relates to an electronic device capable of shielding electronic components.

2. Description of Related Art

Along with rapid development of communication technology industry, information products are widely used, for example, electronic products such as 3G smart phones, personal digital assistants (PDAs) and notebook computers, etc. are frequently used in people's daily life. Utilization of theses electronic products not only greatly improve the convenience of daily life, but also result in time and space compression, so that modem people can closely interact with each other to communicate and exchange messages and knowledge without being limited by geographical boundaries, so as to achieve optimal common interest. Therefore, a wireless radio frequency (RF) circuit plays an important role and makes information transmission and knowledge exchange more convenient and non-blocking.

Performance of a today's wireless communication device is increasingly powerful, and functions of a camera, a voice recorder, a navigation device and a music player are continually integrated therein. On the other hand, the wireless communication devices are miniaturized to achieve features of lightness, slimness, shortness and smallness according to consumer's demand, so that electronic components therein are closely configured, which aggravates a mutual interference effect of signals sent by the electronic components. Therefore, an effective shielding measure is required to ensure operating performance of the wireless communication device.

A commonly used shielding measure is to fabricate a shielding case via sheet metal stamping to separate the electronic components, so as to avoid the mutual interference of the signals. However, regarding a demand of multiple compartments, due to limitation of fabrication processes and consideration of feasibility of sheet metal deployment and stamping, the multiple compartments are hard to be achieved according to the conventional technique. Therefore, it is necessary to provide a shielding case capable of containing a plurality of electronic components and suitable for high density arrangement.

### SUMMARY OF THE INVENTION

The invention is directed to an electronic device, which is used for containing a plurality of electronic components and provide a shielding function thereto.

The invention provides an electronic device including a circuit board, a frame, at least one shielding cover, a shielding case and a plurality of electronic components. The frame is disposed on the circuit board for forming a plurality of first containing spaces on the circuit board. The shielding cover is disposed on the frame and covers at least a part of the first containing spaces. The shielding cover comprises a plurality of folded portions. The folded portions are disposed in a part of the first containing spaces for dividing the first containing spaces into a plurality of second containing spaces. The shielding case is disposed on the circuit board and covers the shielding cover and the frame. The electronic components are disposed on the circuit board and located in at least one of the first containing spaces and the second containing spaces.

In an embodiment of the invention, a material of the frame, the shielding cover and the shielding case includes metal.

In an embodiment of the invention, the at least one shielding cover includes a first shielding cover and a second shielding cover, where the second shielding cover covers the frame, and the first shielding cover covers the second shielding cover.

In an embodiment of the invention, an orthogonal projection of the first shielding cover on the circuit board is partially overlapped to an orthogonal projection of the second shielding cover on the circuit board.

In an embodiment of the invention, the first shielding cover has a plurality of first folded portions, where the first folded portions are inserted in a part of the first containing spaces to divide the first containing spaces into a plurality of third containing spaces.

In an embodiment of the invention, the second shielding cover has a plurality of second folded portions, where the second folded portions are inserted in a part of the third containing spaces to divide the third containing spaces into the second containing spaces.

In an embodiment of the invention, the second shielding cover further has a plurality of grooves disposed corresponding to positions of the first folded portions of the first shielding cover, where the first shielding cover is inlaid to the second shielding cover by penetrating the first folded portions through the corresponding grooves.

In an embodiment of the invention, the frame and a part of the shielding case not covering the first containing spaces form at least one fourth containing space, and one of the electronic devices is located in the fourth containing space.

According to the above descriptions, the shielding cover having a plurality of folded portions is used to further divide the shielding frame, so as to breakthrough the limitation of the conventional fabrication process to produce more containing spaces. In this way, a containing density for the electronic components having the shielding demand is also increased.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an exploded view of an electronic device according to an embodiment of the invention.

FIG. 2 is a combination view of the electronic device of FIG. 1.

FIG. 3 is a top view of the electronic device of FIG. 1.

FIG. 4 is an exploded view of an electronic device according to another embodiment of the invention.

FIG. 5 is a top view of the electronic device of FIG. 4.

### DETAILED DESCRIPTION OF DISCLOSED EMBODIMENTS

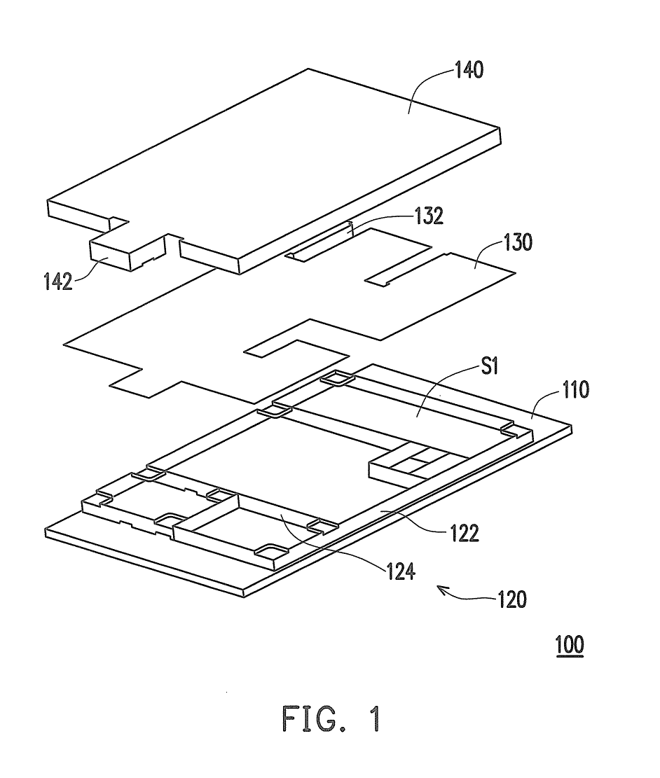

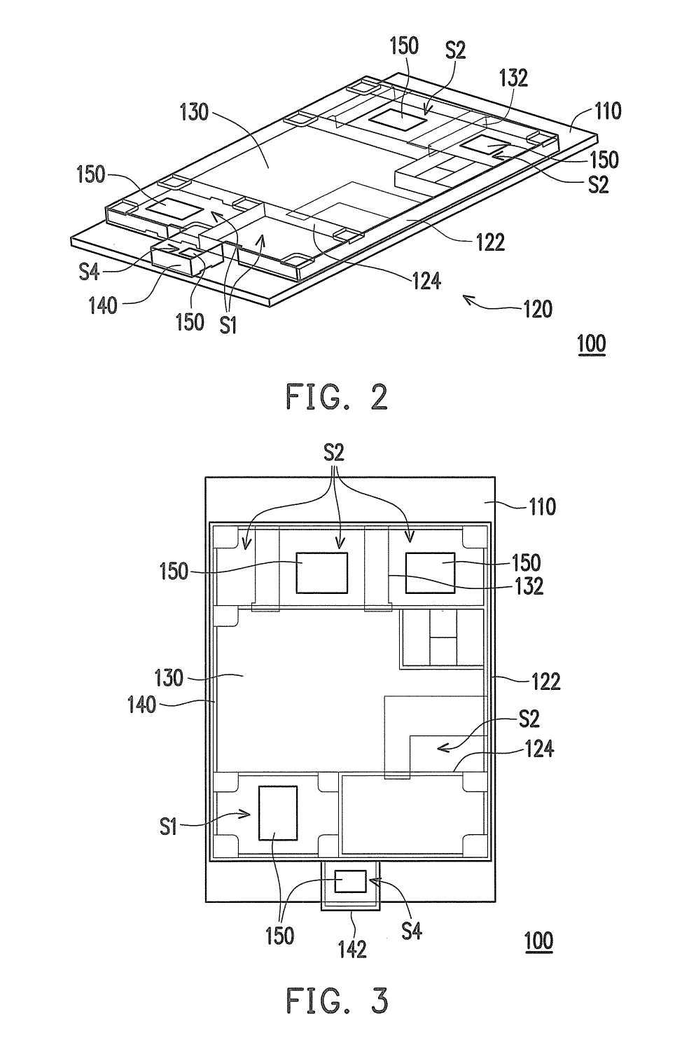

FIG. 1 is an exploded view of an electronic device according to an embodiment of the invention, and FIG. 2 is a combination view of the electronic device of FIG. 1. For simplicity's sake, an internal structure of the electronic device of FIG. 2 is illustrated by fine solid lines. Referring to FIG. 1 and FIG. 2, the electronic device 100 of the present embodiment includes a circuit board 110, a frame 120, at least a shielding cover 130 (one shielding cover is illustrated), a shielding case 140 and a plurality of electronic components 150 (which are represented by thick solid line blocks in FIG. 2). The frame 120 is disposed on the circuit board 110 by, for example, welding, and the frame 120 includes a outer frame 122 and a plurality of spacers 124, where the spacers 124 are inserted in the outer frame 122 to divide a plurality of first containing spaces 51 on the circuit board 110 through connections of the spacers 124 and connections of the spacers 124 and the outer frame 122.

In the present embodiment, the shielding cover 130 is disposed on the frame 120 and covers at least a part of the first containing spaces S1. The shielding cover 130 comprises a plurality of folded portions 132, and the folded portions 132 are disposed in a part of the first containing spaces S1 for dividing the first containing spaces S1 into a plurality of second containing spaces S2. Namely, when the folded portions 132 are inserted in the first containing spaces S1, the first containing spaces S1 having at least one folded portion 132 are further divided into a plurality of the second containing spaces S2, and the electronic components 150 are disposed in at least one of the first containing spaces S1 and the second containing spaces S2. The shielding case 140 is disposed on the circuit board 110 and covers the shielding cover 130 and the frame 120. In this way, the outer frame 122 and the spacers 124 are used to divide a plurality of the first containing spaces S1 on the circuit board 110, and the folded portions 132 of the shielding cover 130 are further inserted in the first containing spaces S1 to separate a plurality of the second containing spaces S2, and then the shielding case 140 covers the shielding cover 130 and the frame 120 to provide more containing spaces suitable for shielding signal interference and electromagnetic interference.

In detail, to achieve the signal and electromagnetic shielding effect, a material of the frame 120, the shielding cover 130 and the shielding case 140 is required to be metal or conductor, which includes steel, copper, alloy and sheet metal, etc., and the frame 120 may include a plurality of brazing welding materials, for example, welding pieces, and each brazing welding material is used to weld one of the spacers 124 to the outer frame 122, or weld one of the spacers 124 to another spacer 124, i.e. a connection between each of the spacers 124 and the outer frame 122 and a connection between each of the spacers 124 and another spacer 124 are implemented by welding one of the brazing welding materials. In the present embodiment, the folded portions 132 are formed integrally with the shielding cover 130. Therefore, the frame 120, the shielding cover 130, the shielding case 140 and the brazing welding materials at the connections thereof are all made of metals or conductors, so that electrostatic equipotentiality of the metals or the conductors can be used to effectively shield electromagnetic interference or signal interference outside the containing spaces.

FIG. 3 is a top view of the electronic device of FIG. 1 (an internal structure of the electronic device is illustrated by fine solid lines). Referring to FIG. 3, in the present embodiment, the shielding case 140 covers the frame 120, and the shielding case 140 has at least one protrusion portion 142 (one protrusion portion is illustrated). The protrusion portion 142 protrudes out from the frame 120 and is not inlaid to the frame 120. The protrusion portion 142 and the frame 120 can form at least one fourth containing space S4, and at least one of the electronic devices 150 is disposed in the fourth containing space S4.

In an embodiment of the invention that is not illustrated, the shielding case is adapted to be engaged to the frame, i.e. the shielding case and the frame respectively have a position limiting structure, and the position limiting structures are corresponded and interfered to each other, so as to position-limit the shielding case to the frame.

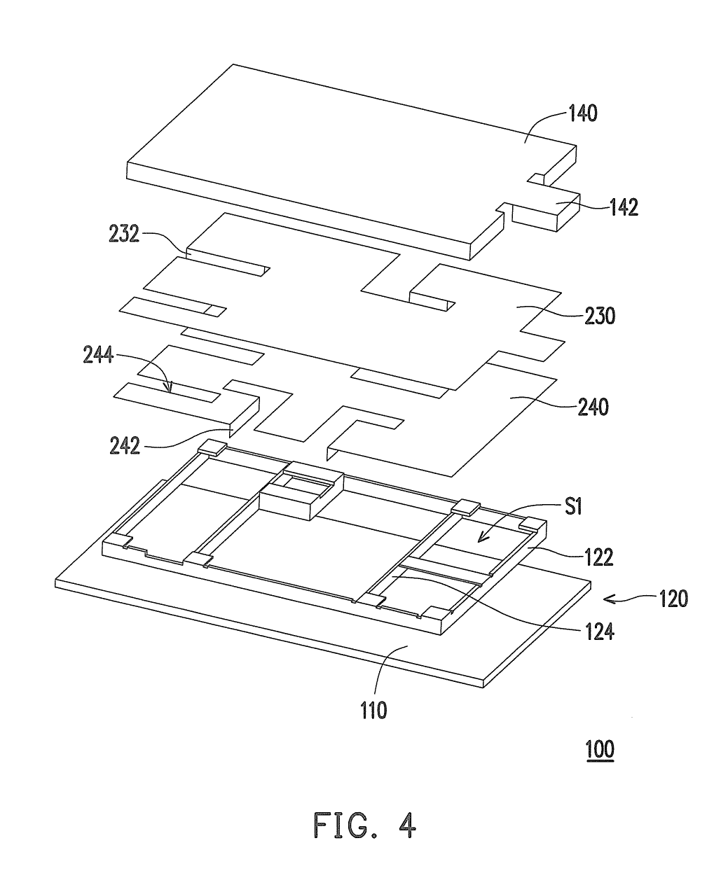

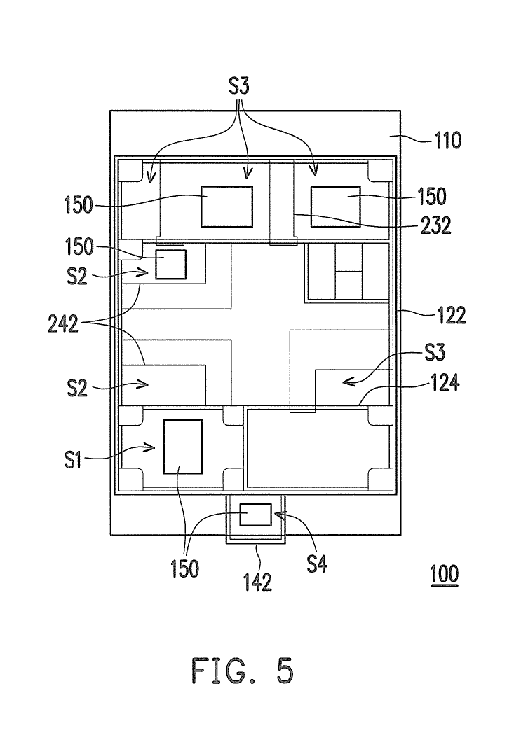

FIG. 4 is an exploded view of an electronic device according to another embodiment of the invention. FIG. 5 is a top view of the electronic device of FIG. 4. For simplicity's sake, an internal structure of the electronic device of FIG. 5 is illustrated by fine solid lines. Referring to FIG. 4 and FIG. 5, the shielding cover 130 includes a first shielding cover 230 and a second shielding cover 240. The first shielding cover 230 has a plurality of first folded portions 232, and the first folded portions 232 are inserted in a part of the first containing spaces S1 to divide the first containing spaces S1 into a plurality of third containing spaces S3.

In the present embodiment, the second shielding cover 240 further has a plurality of second folded portions 242 and a plurality of grooves 244, the second folded portions 242 are inserted in a part of the third containing spaces S3 to divide the third containing spaces S3 into the second containing spaces S2. The grooves 244 are disposed corresponding to positions of the first folded portions 232 of the first shielding cover 230, so that the first shielding cover 230 is inlaid to the second shielding cover 240 by penetrating the first folded portions 232 through the corresponding grooves 244. The first shielding cover 230 covers the second shielding cover 240 and contacts the second shielding cover 240, and an orthogonal projection of the first shielding cover 230 on the circuit board 110 is partially overlapped to an orthogonal projection of the second shielding cover 240 on the circuit board 110. In this way, the first shielding cover 230 is stacked on the second shielding cover 240 through engagement of the first folded portions 232 of the first shielding cover 230 and the grooves 244 of the second shielding cover 240, so as to divide more containing spaces in the frame 120 to contain more electronic components 150.

In summary, in the electronic device of the invention, the shielding cover having a plurality of folded portions is used to further divide the first containing spaces separated by the spacers of the frame into a plurality of the second containing spaces. Moreover, the frame and the protrusion portions on the shielding case that are not inlaid to the frame can commonly separate the fourth containing spaces. In this way, the limitation of the fabrication processes of the conventional technique is broken through, and the number of the containing spaces of the shielding case is increased to enhance a containing density for the electronic components, and space utilization is more economical.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device, comprising:
a circuit board;
a frame, disposed on the circuit board to form a plurality of first containing spaces on the circuit board;
at least one shielding cover, disposed on the frame and covering at least a part of the first containing spaces, comprising a plurality of folded portions, wherein the folded portions are disposed in a part of the first containing spaces for dividing the first containing spaces into a plurality of second containing spaces;
a shielding case, disposed on the circuit board and covering the shielding cover and the frame; and
a plurality of electronic components, disposed on the circuit board and located in at least one of the first containing spaces and the second containing spaces.

2. The electronic device as claimed in claim 1, wherein a material of the frame, the shielding cover and the shielding case comprises metal.

3. The electronic device as claimed in claim 1, wherein the at least one shielding cover comprises a first shielding cover and a second shielding cover, the second shielding cover covers the frame, and the first shielding cover covers the second shielding cover.

4. The electronic device as claimed in claim 3, wherein an orthogonal projection of the first shielding cover on the circuit board is partially overlapped to an orthogonal projection of the second shielding cover on the circuit board.

5. The electronic device as claimed in claim 3, wherein the first shielding cover has a plurality of first folded portions, and the first folded portions are inserted in a part of the first containing spaces to divide the first containing spaces into a plurality of third containing spaces.

6. The electronic device as claimed in claim 3, wherein the second shielding cover has a plurality of second folded portions, and the second folded portions are inserted in a part of the third containing spaces to divide the third containing spaces into the second containing spaces.

7. The electronic device as claimed in claim 3, wherein the second shielding cover further has a plurality of grooves disposed corresponding to positions of the first folded portions of the first shielding cover, wherein the first shielding cover is inlaid to the second shielding cover by penetrating the first folded portions through the corresponding grooves.

8. The electronic device as claimed in claim 1, wherein the frame and a part of the shielding case not covering the first containing spaces form at least one fourth containing space, and one of the electronic devices is located in the fourth containing space.
